(19) United States
(12) Patent Application Publication
(10) Pub. No.: US 2014/0264059 A1
(43) Pub. Date: Sep. 18, 2014

(54) LIGHT IRRADIANCE AND THERMAL MEASUREMENT IN UV AND CVD CHAMBERS

(71) Applicant: Applied Materials, Inc., Santa Clara, CA (US)

(72) Inventors: Sanjeev BALUJA, Campbell, CA (US); Tuan Anh NGUYEN, San Jose, CA (US); Abhijit KANGUDE, Santa Clara, CA (US); Bozhi YANG, Santa Clara, CA (US); Amit Kumar BANSAL, Sunnyvale, CA (US); Inna TUREVSKY, Santa Clara, CA (US); Scott A. HENDRICKSON, Brentwood, CA (US); Juan Carlos ROCHA- ALVAREZ, San Carlos, CA (US); Thomas NOWAK, Cupertino, CA (US)

(21) Appl. No.: 14/174,378

(22) Filed: Feb. 6, 2014

Related U.S. Application Data
(60) Provisional application No. 61/788,170, filed on Mar. 15, 2013.

(51) Int. Cl. H01L 21/66

(52) U.S. Cl. CPC H01L 22/30
USPC 250/393

(57) ABSTRACT

Embodiments of a semiconductor processing chamber described herein include a substrate support, a source of radiant energy opposite the substrate support, a window between the source of radiant energy and the substrate support, a detector sensitive to the radiant energy positioned to detect the radiant energy transmitted by the window, and a detector sensitive to radiation emitted by the substrate positioned to detect radiation emitted by the substrate. The chamber may also include a showerhead. The substrate support may be between the detectors and the window. A second radiant energy source may be included to project energy through the window to a detector. The second radiant energy source may also be located proximate the first radiant energy source and the detectors.

### CROSS-REFERENCE TO RELATED APPLICATIONS

This application claims benefit of U.S. provisional patent application Ser. No. 61/788,170, filed Mar. 15, 2013, which is herein incorporated by reference.

### FIELD

Embodiments described herein generally relate to methods and apparatus for forming thin films. More specifically, embodiments described herein provide methods and apparatus for monitoring UV and/or IR irradiance and thermal measurement during processing in UV and CVD chambers.

### BACKGROUND

Material and energy processes are common in semiconductor manufacturing. Semiconductor substrates are frequently subjected to thermal treatments, UV treatments, and material processes such as deposition and etching that involve thermal and/or UV energy. Energy sources used in chambers that also perform material processes are typically separated from the processing environment by a barrier that is transparent to the energy. For example, a quartz window is often used to separate a UV source from the substrate processing area in the chamber. Such measures prevent fouling or degradation of the energy source from process gases.

During such material and energy processes, it is often desired to monitor the temperature of the substrate. Thermal processing is an important component of semiconductor manufacturing, and the thermal history of a substrate can be a critical variable in performance of the finished device. Temperature of the substrate is commonly measured by detecting thermal radiation emitted by the substrate.

The radiant energy processes described above depend on clear transmission of radiation from source to target. In the UV case above, the window is typically selected to be substantially transparent to the UV radiation. In the thermal case, a detector needs an unobstructed view of the radiation emitted by the substrate. Fouling or degradation of transmissive components in the chamber can lead to unwanted trending in the amount of radiation detected. The window separating the UV source from the processing environment may become clouded by deposition or frosted by etching, reducing transmission of UV energy into the chamber. Detectors disposed in line-of-sight view of a substrate may become clouded by deposition or etching. There is a need for improved methods and apparatus of monitoring and delivering radiation in substrate processing chambers.

### SUMMARY OF THE INVENTION

Embodiments of a semiconductor processing chamber described herein include a substrate support, a source of radiant energy opposite the substrate support, a window between the source of radiant energy and the substrate support, a detector sensitive to the radiant energy positioned to detect the radiant energy transmitted by the window, and a detector sensitive to radiation emitted by the substrate positioned to detect radiation emitted by the substrate. The chamber may also include a showerhead. The substrate support may be between the detectors and the window. A second radiant energy source may be included to project energy through the window to a detector. The second radiant energy source may also be located proximate the first radiant energy source and the detectors.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic cross-sectional view of a processing chamber according to one embodiment.

FIG. 1B is a top view of the processing chamber of FIG. 1A.

FIG. 1C is a detailed cross-sectional view of a portion of the chamber of FIG. 1A according to one embodiment.

FIG. 1D is a detailed cross-sectional view of a portion of the chamber of FIG. 1A according to another embodiment

FIG. 2 is a schematic cross-sectional view of a processing chamber according to another embodiment.

FIG. 3 is a schematic cross-sectional view of a processing chamber according to another embodiment.

FIG. 4 is a schematic cross-sectional view of a processing chamber according to another embodiment.

FIG. 5 is a schematic cross-sectional view of a processing chamber according to another embodiment.

FIG. 6 is a schematic cross-sectional view of a processing chamber according to another embodiment

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

FIG. 1A is a schematic cross-sectional view of a processing chamber 100 according to one embodiment. The processing chamber 100 has a chamber body 104 and a substrate support 102 enclosed by the chamber body 104. A radiation source 106 is disposed opposite a substrate receiving surface 122 of the substrate support 102. The radiation source 106 may be a thermal source or a UV source. A window 108, which may be quartz or any other suitable material, separates the radiation source 106 from the processing environment proximate the substrate receiving surface 122.

The chamber 100 may include a showerhead 144, if the chamber 100 is configured to perform a material process. If the chamber 100 is configured to perform an energy process, such as UV treatment, the showerhead may be omitted. Thus, the showerhead 144 is optional. If the showerhead 144 is included, it is typically made of a material that allows passage of radiation from the radiation source 106 through the showerhead 144. In some cases, the showerhead may be quartz or calcium fluoride.

The substrate receiving surface 122 separates the chamber 100 into a processing region 132 and a non-processing region 134. A radiation conduit 110 is disposed in the substrate receiving surface 122. The radiation conduit 110 passes radiation through the substrate receiving surface 122 from the processing region 132 to the non-processing region 134. The radiation may be UV radiation or thermal radiation. The UV radiation may be from a UV source in the radiation source 106. The thermal radiation may be from a thermal source in the radiation source 106, or from a substrate disposed on the substrate receiving surface 122.

A detector 114 is disposed in the non-processing region 134, proximate a floor of the chamber 100, to detect radiation passed by the radiation conduit 110 into the non-processing region 134. The detector 114 may be sensitive to radiation emitted by the radiation source 106 or the substrate, or both. Thermal radiation emitted by the substrate may be detected by the detector 114 to monitor a thermal state of the substrate, such as temperature. UV or thermal radiation emitted by the radiation source 106 may be detected by the detector 114 to monitor a change in transmissivity of the substrate, a change in transmissivity of the window 108, or a change in emissivity of the radiation source 106.

The detector 114 may be surrounded by a shield 116. The shield may be a waveguide, or the shield may be a shade that reduces ambient radiation around the detector 114 to improve signal to noise ratio.

A second radiation conduit 112 may be disposed in the substrate receiving surface 122. The second radiation conduit 112 may be the same material as the radiation conduit 110, or a different material. The radiation conduit 110 may be a first material that is substantially transparent to radiation of a first spectrum, while the second radiation conduit 112 is a second material that is substantially transparent to radiation of a second spectrum. In this way the first and second radiation conduits 110 and 112 may facilitate monitoring two different radiation spectra. A second detector 118 and shield 120 may be provided to facilitate independent monitoring of two spectra concurrently or simultaneously.

The shields 116/120 are shown in FIG. 1A as having a single opening directed toward the respective radiation conduits 110/112. The shields 116/120 may have openings oriented in other directions to sample radiation at other locations in the chamber 100. An opening may be directed to a reflector positioned at a monitoring location of the chamber 100 in some cases. Radiation from the reflector may indicate deposition on the reflector, or may indicate conditions at the source of the radiation or elsewhere along the optical path of the radiation. The openings may have closures that are independently operated, if desired, to change the source of radiation into the detectors 114/118 at will. The shields 116/120 may also be actuated to rotate, thus directing openings at different locations in the chamber 100. The rotation may be along a longitudinal axis of the shields 116/120, or along some other axis, and the rotation may be continuous or intermittent. For example, a single detector may be positioned in view of all UV emitters in the UV source 108, and a waveguide positioned around the detector may rotate to collect radiation from each UV emitter in turn. Further, a detector such as the detectors 114/118 may be actuated to rotate similarly to view different locations in the chamber 100 and/or different UV emitters.

The chamber 100 may be a UV treatment chamber or a thermal processing chamber, such as a CVD chamber, a PECVD chamber, an ALD chamber, an epitaxy chamber, or other processing chamber. The substrate support 102 may rotate to facilitate uniform processing. If the substrate support 102 rotates, the radiation conduits 110 and 112 transmit a radiation column to the non-processing region that moves as the substrate support 102 rotates. As a radiation column reaches one of the detectors 114/118, the detector may register a response that represents an intensity of the radiation column. In this way, radiation transmitted by the radiation conduits 110/112 may be monitored periodically as the radiation column from the radiation conduits 110/112 passes by the detectors 114/118. Locating the detectors 114/118 on the chamber floor reduces the opportunity for process gases to degrade the detectors 114/118.

FIG. 1B is a top view of the chamber 100 according to another embodiment. The chamber body 104 is visible enclosing the substrate receiving surface 122. Four radiation conduits are visible in the substrate receiving surface 122, two of the radiation conduit 110 and two of the second radiation conduit 112. In the embodiment of FIG. 1B, four radiation columns are transmitted to the non-processing region 134 (FIG. 1A) for analysis by the detectors 114/118. The detectors 114/118 may be configured to detect different spectra, as noted above, so the detector 114 may be configured to detect the radiation column transmitted by the first radiation conduit 110 while the detector 118 may be configured to detect the radiation column transmitted by the second radiation conduit 112. As the substrate receiving surface 122 of FIG. 1B rotates, radiation columns of alternating type move across each of the detectors 114/118. Each time a radiation column moves across the detectors 114/118, the detectors 114/118 will alternate registering a signal because the two radiation columns illuminating the two detectors 114/118 will be of the same type, either the type transmitted by the radiation conduit 110 or the type transmitted by the radiation conduit 112. Thus, either the detector 114 or the detector 118 will register a signal.

The radiation conduits 110 and 112 are disposed in the substrate support 102 in the substrate receiving surface 122 thereof so as not to be displaced by motion of the substrate support 102. FIG. 1C is a detailed cross-sectional view of a portion of the chamber 100 of FIG. 1A according to one embodiment. FIG. 1C shows one way in which a radiation conduit, for example the radiation conduit 110, may be disposed in the substrate receiving surface 122. In FIG. 1C, the radiation conduit 110 is disposed in an opening 136 through the substrate receiving surface 122. A ledge 126 formed at a first end 138 of the opening 136 supports the radiation conduit 110 in the opening 136. The radiation conduit 110 may rest slightly inside the substrate receiving surface 122 at a second end 140 thereof so that the radiation conduit 110 does not protrude above the substrate receiving surface 122 and contact a substrate disposed thereon.

FIG. 1D is a detailed cross-sectional view of a portion of the chamber 100 of FIG. 1A according to another embodiment. FIG. 1D shows another way in which a radiation conduit, for example the radiation conduit 110, may be disposed in the substrate receiving surface 122. In FIG. 1D, the radiation conduit 110 is disposed in an opening 136 that has a shelf 130 formed at an end of the opening proximate a substrate contact zone 128 of the substrate receiving surface 122. The radiation conduit 110 has an edge extension 142 that engages the shelf 130 to support the radiation conduit 110 in the opening 136. The radiation conduit 110 may be recessed into the substrate receiving surface 122, if desired, to avoid contact between the radiation conduit 110 and a substrate disposed at the substrate contact zone 128.

FIG. 2 is a schematic cross-sectional view of a processing chamber 200 according to another embodiment. The processing chamber 200 includes the chamber body 104, the radiation source 106 and the window 108, and a substrate support 202 featuring a plurality of openings 204 in a substrate receiving surface 222 thereof. The first detector 114 and second detector 118 are located in positions similar to those in the chamber 100. Radiation conduits 206 and 208 are coupled to the detectors 114/118, respectively, rather than being disposed in the substrate receiving surface 222. The openings 204 may be arranged in patterns similar to the openings 136, in which the radiation conduits 110 and 112 of the chamber 100 are disposed. The openings 204 may be coated or treated to facilitate transmission of radiation through the openings 204 to the radiation conduits 206/208 and the detectors 114/118. As with the chamber 100, the substrate support 202 may rotate, such that as the openings 204 move over the detectors 114/118, radiation specific to each detector generates a signal for monitoring radiation transmitted or emitted by the substrate. The chamber 200 may also include the showerhead 144, if desired.

FIG. 3 is a schematic cross-sectional view of a processing chamber 300 according to another embodiment. The chamber 300 includes the chamber body 104, the UV source 106 and the window 108. A substrate support 302 is disposed inside the chamber body 104, the substrate support 302 including a substrate receiving surface 304 that has a first detector 306 attached to an underside of the substrate receiving surface 304 and coupled to a radiation conduit 308 disposed through the substrate receiving surface 304. The radiation conduit 308 may be disposed through the substrate receiving surface 304 in the manner depicted in FIG. 1C or FIG. 1D. A second detector 310 is attached to the underside of the substrate receiving surface 304, and is positioned to receive radiation through an opening 312, with no radiation conduit disposed within the opening 312. The configuration of the second detector 310 is intended to show that a detector may be attached to the substrate receiving surface 304 with or without a radiation conduit, depending on the needs of specific embodiments. A third detector 314 may be embedded in the substrate support 302 and coupled to a second radiation conduit 316 disposed in the substrate receiving surface 304. Each of the detectors 306/310/314 may include a wireless transmitter to send signals to receivers outside the chamber 300, as well as a local power source (i.e. battery). Alternately, each of the detectors 306/310/314 may be electrically coupled to receivers and power sources outside the chamber through electrical conduits disposed through the substrate support 304 (not shown). A slip ring 318 may be included to facilitate making an electrical connection between static components, such as receivers and power sources, and the rotating substrate support 304. The chamber 300 may also include the showerhead 144, if desired.

FIG. 4 is a schematic cross-sectional view of a processing chamber 400 according to another embodiment. The chamber 400 includes the chamber body 104 and the window 108, and may also include the showerhead 144. A substrate support 402 is disposed inside the chamber body. A first light source 410 is disposed inside the chamber body 104 to fill the chamber 400 with radiant energy.

A radiation detector 406, optionally with a radiation conduit 408, is disposed in a UV source 404, or in the chamber lid, such that radiation from the radiation source 410 may be detected by the detector 406 through the window 108. The detector 406 may, for example, be located between one or more UV emitters located in the UV source 404. The radiation source 110 may be a UV source having a different spectrum from the UV source 404, or may be a visible or infrared source to facilitate independent monitoring of UV emissions from the UV source 404 and fouling of the window 108 by process materials. The detector 406 may include a detector sensitive to UV radiation emitted by the UV source 406, in order to monitor operation of the UV emitters of the UV source 406. The detector 406 may also include a detector sensitive to radiation emitted by the radiation source 410 to monitor radiation transmitted by the window 108.

Radiation transmitted by the window 108, when compared to radiation emitted by the radiation source 410, reveals a degree of fouling or frosting of the window 108, indicating reduction of UV radiation transmitted from the UV source 406 into the process chamber. An end point may be detected at which the window 108 may be cleaned. A second radiation source 412 may be included in the chamber to monitor a second spectrum and/or location of the window 108, if desired. It should be noted that the radiation sources 410/412 may be located anywhere in the chamber 400, including on the chamber floor. The radiation sources 410/412 may fill the chamber 400 with radiation from any location within the chamber 400, and that radiation may be monitored by the detector 406. Any number of radiation sources such as the radiation sources 410/412 may be included in the chamber 400 to monitor different spectra of radiation and different transmission characteristics of the window 108 at different wavelengths, if desired.

FIG. 5 is a schematic cross-sectional view of a processing chamber 500 according to another embodiment. The processing chamber 500 includes the chamber body 104, the UV source 106, and the window 108, and may also include the showerhead 144. A substrate support 502 having an opening 504 in a substrate receiving surface 522 thereof is disposed inside the chamber body 104. A radiation source 506 is disposed on a floor of the chamber 500 in alignment with the opening 504. A detector 510 is disposed in a lid of the chamber 500, and may be located inside the UV source 106 or outside the UV source 106, as shown in FIG. 5. A radiation conduit 508 may be coupled to the detector 510. The detector 510 and the radiation conduit 508 are in optical alignment with the opening 504 and the radiation source 506 to facilitate measurement of radiation from the radiation source 506 received at the detector 510. Such radiation may indicate a thermal state of the substrate by virtue of radiation transmitted or emitted by the substrate, or the radiation may indicate a transparency of the window 108, which in turn indicates degradation in transmission of UV radiation from the UV source 106 into the chamber 500.

As the substrate support 502 rotates, the opening 504 periodically aligns with the radiation source 506 and the detector 510 and radiation conduit 508 to generate a signal indicating radiation received at the detector 510. More than one such source, opening, detector combination may be included in the chamber 500, if desired, to facilitate monitoring the substrate and/or the window at different locations.

FIG. 6 is a schematic cross-sectional view of a processing chamber 600 according to another embodiment. The chamber 600 includes the chamber body 104, the window 108, and the substrate support 402, and a UV source that includes a radiation transceiver 604. The chamber 600 may also include the showerhead 144. The radiation transceiver 604 may include one or more radiation emitters that emit different spectra to monitor different aspects of the chamber 600. The radiation transceiver 604 includes a detector sensitive to each spectrum emitted by a radiation emitter in the transceiver 604. The transceiver 604 may also include a detector sensitive to radiation emitted by a substrate disposed on the substrate support. The radiation transceiver 604 may also include a detector sensitive to radiation emitted by UV emitters of the UV source 602. In this way, the radiation transceiver 604 may independently monitor substrate thermal state, UV emitter degradation, and window transmission degradation.

The various embodiments of sensors described herein may also be used to monitor the output of individual UV lamps or bulbs, if desired. For example, the output of individual UV lamps or bulbs may be determined by lighting one lamp or bulb at a time and measuring the intensity using the sensors described herein. The readings for each lamp or bulb may then be compared to determine which lamp or bulb, if any, needs replacing.

The shields 116/120 of FIG. 1A are each depicted with an opening that aligns with the radiation conduits 110/112. The shields 116/120 may have other openings that allow collection of radiation from other locations in the chamber 100. Multiple openings may allow collection of radiation from multiple locations in the chamber 100. For example, a sensor such as the detectors 114/118 may be located in view of all UV emitters in the UV source 106, and a light guide may be coupled to the sensor, wherein the light guide has a plurality of opening, each opening positioned to collect radiation emitted by one UV emitter in the UV source 106. The openings may each have a closure that may be independently operated so that each UV emitter may be independently probed by opening the desired portal of the light guide.

A rotatable light guide may also be coupled to a sensor in some embodiments. The rotatable light guide may be rotated to collect radiation from any desired location in the chamber 100. For example, the rotatable light guide may be oriented to collect radiation from a UV emitter, from the substrate, or from a chamber surface to monitor evolution of optical properties and/or thermal state. If a chamber location is not in direct view of the sensor with the rotatable light guide, a reflector may be included to direct radiation from the location of interest to the rotatable light guide. The rotation of the light guide may be at will, actuated by a controlled actuator, or the rotation may be continuous at a constant or changing rate, or the rotation may be intermittent. In alternate embodiments, the sensor itself may rotate.

While the foregoing is directed to embodiments of the present invention, other and further embodiments of the invention may be devised without departing from the basic scope thereof, and the scope thereof is determined by the claims that follow.

We claim:

1. A semiconductor processing chamber, comprising:
a substrate support;
a source of radiant energy opposite the substrate support;
a window between the source of radiant energy and the substrate support;
a detector sensitive to the radiant energy positioned to detect the radiant energy transmitted by the window; and
a detector sensitive to radiation emitted by the substrate positioned to detect radiation emitted by the substrate.

2. The semiconductor processing chamber of claim 1, wherein the substrate support is between the detectors and the window.

3. The semiconductor processing chamber of claim 2, further comprising a waveguide proximate each detector.

4. The semiconductor processing chamber of claim 3, further comprising an opening formed in the substrate support at a location that is aligned with the detectors.

5. The semiconductor processing chamber of claim 4, further comprising a radiation conduit disposed in the opening.

6. The semiconductor processing chamber of claim 1, further comprising a second source of radiant energy positioned to direct radiant energy to at least one of the detectors.

7. The semiconductor processing chamber of claim 6, wherein the window is between the second source of radiant energy and the substrate support.

8. The semiconductor processing chamber of claim 6, wherein the window is between the second source of radiant energy and the detectors.

9. The semiconductor processing chamber of claim 6, wherein the substrate support is between the second source of radiant energy and the detectors.

10. The semiconductor processing chamber of claim 1, further comprising a showerhead between the window and the substrate support.

11. A semiconductor processing chamber, comprising:
a substrate support;
a first source of radiant energy opposite the substrate support;
a window between the source of radiant energy and the substrate support;
a showerhead between the window and the substrate support;
a detector sensitive to the radiant energy positioned to detect the radiant energy transmitted by the window; and
a detector sensitive to radiation emitted by the substrate positioned to detect radiation emitted by the substrate.

12. The semiconductor processing chamber of claim 11, wherein the substrate support is between the detectors and the window.

13. The semiconductor processing chamber of claim 12, further comprising a waveguide proximate each detector.

14. The semiconductor processing chamber of claim 13, further comprising an opening formed in the substrate support at a location that is aligned with the detectors.

15. The semiconductor processing chamber of claim 14, further comprising a radiation conduit disposed in the opening.

16. The semiconductor processing chamber of claim 11, further comprising a second source of radiant energy positioned to direct radiant energy to at least one of the detectors.

17. The semiconductor processing chamber of claim 16, wherein the window is between the second source of radiant energy and the substrate support.

18. The semiconductor processing chamber of claim 16, wherein the window is between the second source of radiant energy and the detectors.

19. The semiconductor processing chamber of claim 16, wherein the substrate support is between the second source of radiant energy and the detectors.

20. The semiconductor processing chamber of claim 16, wherein the second source of radiant energy and the detectors are located proximate the first source of radiant energy.
